(19) United States
(12) Patent Application Publication
(10) Pub. No.: US 2015/0177328 A1
(43) Pub. Date: Jun. 25, 2015

(54) AUTOMATED MOTOR ADAPTATION

(71) Applicant: Danfoss Power Electronics A/S, Graasten (DK)

(72) Inventor: Michael Harke, Madison, WI (US)

(21) Appl. No.: 14/420,004

(22) PCT Filed: Jul. 11, 2013
(86) PCT No.: PCT/IB2013/055692

§ 371 Date: Feb. 6, 2015

Related U.S. Application Data
(60) Provisional application No. 61/681,180, filed on Aug. 9, 2012.

(51) Int. Cl. G01R 31/34; G01R 31/28; G01R 19/00; G01R 27/14; G01R 27/26

(52) U.S. Cl. CPC G01R 31/343; G01R 27/14; G01R 27/2611; G01R 19/0084; G01R 19/0092; G01R 31/2837

(57) ABSTRACT

A method of determining electromagnetic characteristics of an asynchronous motor system is described. A DC sequence is applied comprising DC vectors applied to different phases of the motor in tum. An AC sequence is also applied to different phases of the motor, the AC sequence including pulses having different DC offsets being applied to different phases of the motor. The DC and AC pulses are applied such that any torque generated is minimized. The data obtained is used to calculate the stator and rotor resistances of the motor, the non-linearity of an inverter of the motor system and the nominal stator transient and magnetizing inductances of the motor.

### CROSS-REFERENCE TO RELATED APPLICATION

This application is entitled to the benefit of and incorporates by reference subject matter disclosed in International Patent Application No. PCT/IB2013/055692 filed on Jul. 11, 2013 and U.S. Patent Application 61/681,180 filed Aug. 9, 2012.

### FIELD OF THE INVENTION

The present invention relates a mechanism for determining the electromagnetic characteristics of an asynchronous motor.

### BACKGROUND

FIG. 1 is a highly schematic block diagram, indicated generally by the reference numeral 1, of a known motor system. The motor system 1 comprises an AC power source 2, a rectifier 4, a DC link capacitor 6, an inverter module 8, a three-phase motor 10 and a controller 12.

As is well known in the art, the rectifier 4 converts AC electrical power provided by the AC power source 2 into a DC source at the DC link capacitor 6. The inverter module 8 comprises a number of switching elements, typically insulated gate bipolar transistors (IGBTs), that are used to convert the DC signal at the DC link capacitor 6 into three AC signals that are provided to each of the phases of the motor 10. The controller 12 provides switching instructions for each of the switching elements of the inverter module 8. Thus, the controller 12 is able to precisely control the frequency and phase of each of the signals provided to the motor 10.

The controller 12 may, for example, be used to control the motor 10 in order to provide a desired speed and/or torque. In order to enable accurate control, it is necessary for the controller 12 to take into account the electromagnetic properties of the motor 10.

One method is to use data sheet information relating to the motor 10. However, even when this information is available, it is often insufficiently precise and accurate to enable accurate and efficient control of the motor 10.

An alternative to using data sheet information is to measure the characteristics of the motor itself. For example, it is known to use the controller 12 to control the injection of signals into the motor 10, to monitor the response to those signals and to estimate various resistances and inductances of the motor 10 on the basis of those responses.

In some cases, it is desirable to inject large currents into the motor to mitigate nonlinearities caused by the inverter or explore other nonlinearities such as magnetic saturation. Injecting large currents into a motor can cause significant heat generation and can cause damage to the motor and/or the inverter. Further, some existing methods for obtaining data regarding the characteristics of the motor 10 are slow.

Many existing methods require the motor 10 to rotate in order to determine the electrical and magnetic properties of the motor. With the motor 10 installed within a system, this may often be undesirable. It would therefore be advantageous in some circumstances to enable such data to be obtained with the motor at standstill.

The present invention seeks to address at least some of the problems outlined above.

### SUMMARY

The present invention provides a method of determining electromagnetic characteristics of an asynchronous motor system (for example a multi-phase (e.g. three-phase) asynchronous motor system), the method comprising applying a DC sequence to the motor system and applying an AC sequence to the motor system, wherein the DC sequence includes applying a first DC sequence to a first phase of the motor system and applying a second DC sequence to a second phase of the motor system and the AC sequence includes applying an AC sequence to a third and/or a fourth phase of the motor system (which may be the first and second phases respectively), the first and second DC sequences each comprising: setting a first DC current level for application to the motor system and measuring the current(s) and/or the voltage(s) applied to the motor system in response to the setting of the first DC current level; adjusting the DC current level applied in the first DC sequence and measuring current(s) and/or voltage(s) applied to the motor in response to the adjusted DC current level; and repeating the adjusting and measuring step until the respective DC sequence is complete.

For each DC current level applied during one of the DC sequences, the motor may be given time to settle before the voltage and/or current measurements are taken. For example, the method may further comprise monitoring currents applied to the motor to determine when the applied DC current level has settled. Alternatively, a simple delay could be used. Providing a delay is simpler to implement, but measuring when settling has occurred is likely to be more accurate and quicker.

In one form of the invention, the AC sequence includes applying a first AC sequence to the third phase of the motor system (which may be the same as the first phase) and applying a second AC sequence to the fourth phase of the motor system (which may be the same as the second phase), the first and second AC sequences each comprising: setting a first DC offset level; applying one or more AC signals to the respective phase of the motor system, the AC signals including the set DC offset level and measuring the current(s) and/or the voltage(s) applied to the motor system in response to the applied AC signals; adjusting the DC offset level, applying one or more AC signals to the respective phase of the motor system including the adjusted DC offset level and measuring current(s) and/or voltage(s) applied to the motor in response to the applied signal; and repeating the adjusting and measuring step until the respective AC sequence is complete.

The present invention also provides a method of determining electromagnetic characteristics of an asynchronous motor system (such as a multi-phase (e.g. three-phase) asynchronous motor system), the method comprising applying a DC sequence to the motor system and applying an AC sequence to the motor system, wherein the DC sequence includes applying a DC sequence to a first and/or a second phase of the motor system and the AC sequence includes applying a first AC sequence to a third phase of the motor system (which may be the same as the first phase) and applying a second AC sequence to a fourth phase of the motor system (which may be the same as the second phase), the first and second AC sequences each comprising: setting a first DC offset level; applying one or more AC signals to the respective phase of the motor system, the AC signals including the set DC offset level and measuring the current(s) and/or the voltage(s) applied to the motor system in response to the applied AC signals; adjusting the DC offset level, applying one or more AC signals to the respective phase of the motor system including the adjusted DC offset level and measuring current(s) and/or voltage(s) applied to the motor in response to the applied signal; and repeating the adjusting and measuring step until the respective AC sequence is complete.

Applying one or more AC signals to the respective phase of the motor system may comprise applying one or more of a high frequency signal (typically used for estimating transient machine inductance—perhaps having a frequency of 4-6 times the rated machine frequency), a low frequency signal (typically used for estimating mutual (magnetising) inductance) and a slip frequency (typically used to estimate rotor resistance).

In some forms of the invention, the DC offset levels of the AC sequences are spread out amongst the phases of the motor system in such a way that the total power losses are approximately equivalent for each phase.

The DC and AC sequences may be applied such that any torque created within the motor system is minimized (and ideally is not sufficient to rotate a shaft of the motor system). (There is a phenomena referred as remnant magnetism: the stator iron is a soft magnetic material and can be lightly magnetized. Applying a current to the machine leads to remnant magnetism and can cause slight torque production in the machine. This is unavoidable.)

The DC sequence further may comprise applying a third DC sequence to a fifth phase of the motor system.

The AC sequence may further comprise applying third AC sequence to a sixth phase of the motor system.

The invention may involve using data obtained from the application of the DC sequence to determine the stator resistance of the motor and/or the non-linearity of an inverter used to drive the motor.

In one form of the invention, data obtained from the application of the AC sequence is used to determine the nominal stator transient inductance, the magnetizing inductance and/or the rotor resistance of the motor. However, as alluded to by FIGS. 3 and 12 discussed below, there are an infinite number of equivalent circuits that can be generated by adjusting how the leakage inductance are parsed. The present invention can identify the fundamental parameters of the induction machine, regardless of how those fundamental parameters are represented in an equivalent circuit.

The first and second phases of the motor system may be selected from: a positive U vector, a negative U vector, a positive V vector, a negative V vector, a positive W vector and a negative W vector.

The third and fourth phases of the motor system may be selected from: a positive U vector, a negative U vector, a positive V vector, a negative V vector, a positive W vector and a negative W vector.

### BRIEF DESCRIPTION OF THE DRAWINGS

The invention will now be described in further detail with reference to the following schematic drawings, in which:

FIG. 1 is a block diagram of a known motor system;

FIG. 2 is a flow chart of an algorithm in accordance with an aspect of the present invention;

FIG. 3 is an electrical equivalent circuit of an asynchronous motor;

FIG. 4 is a flow chart of a DC sequence in accordance with an aspect of the present invention;

FIG. 5 is a vector diagram of a three-phase asynchronous motor;

FIG. 6 is a vector diagram of a three-phase asynchronous motor;

FIG. 7 shows a detail of part of the flow chart of FIG. 4;

FIG. 8 is a block diagram of a system in accordance with an aspect of the present invention;

FIG. 9 shows a plot of applied currents of an exemplary DC sequence;

FIG. 10 shows a plot of measured currents and voltages of an exemplary DC sequence;

FIG. 11 shows an exemplary Uₑ curve;

FIG. 12 is an alternative electrical equivalent circuit of an asynchronous motor;

FIG. 13 is a flow chart of a AC sequence in accordance with an aspect of the present invention;

FIG. 14 shows a plot of applied currents of an exemplary AC sequence;

FIG. 15 is a block diagram of a compensation mechanism that may be used when applying an AC sequence in accordance with an aspect of the present invention;

FIG. 16 is a block diagram of an alternative compensation mechanism; and

FIG. 17 is a block diagram of a further compensation mechanism.

### DETAILED DESCRIPTION

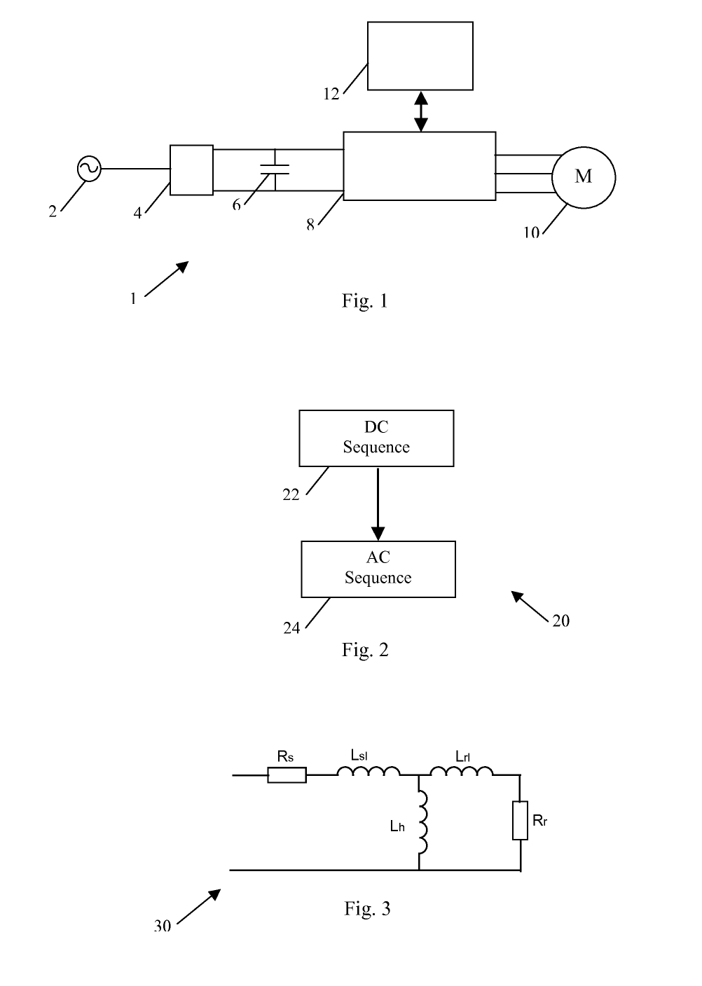

FIG. 2 is a flow chart of an algorithm, indicated generally by the reference numeral 20, in accordance with an aspect of the present invention.

The algorithm 20 starts at step 22, where a DC sequence is performed. As described in detail below, the DC sequence is used to measure the non-linearity of the inverter 8 and to measure the equivalent stator resistance Rₛ of the motor 10, which may include resistive effects in the inverter and in cabling.

Next, the algorithm moves to step 24, where an AC sequence is performed. The algorithm 20 then terminates. As described below, the AC sequence is used to measure the nominal stator transient inductance, magnetizing inductance and rotor resistance of the motor 10.

FIG. 3 is an electrical equivalent circuit of an asynchronous motor, such as the motor 10 described above, when the motor is at standstill. The equivalent circuit, indicated generally by the reference numeral 30, includes a stator resistance Rₛ, a stator leakage inductance Lₛₗ, a mutual inductance Lₕ, a rotor leakage inductance Lᵣₗ and a rotor resistance Rᵣ. The rotor inductance Lᵣ and the stator inductance Lₛ are readily calculated as follows: Lᵣ=Lₕ+Lᵣₗ; and Lₛ=Lₕ+Lₛₗ.

As indicated above, the DC sequence 22 is used to measure the stator resistance Rₛ. A DC sequence is used since, at DC, the various inductances shown in the equivalent circuit 30 behave as short-circuits and so the electrical equivalent circuit 30 can be approximated to the stator resistance Rₛ.

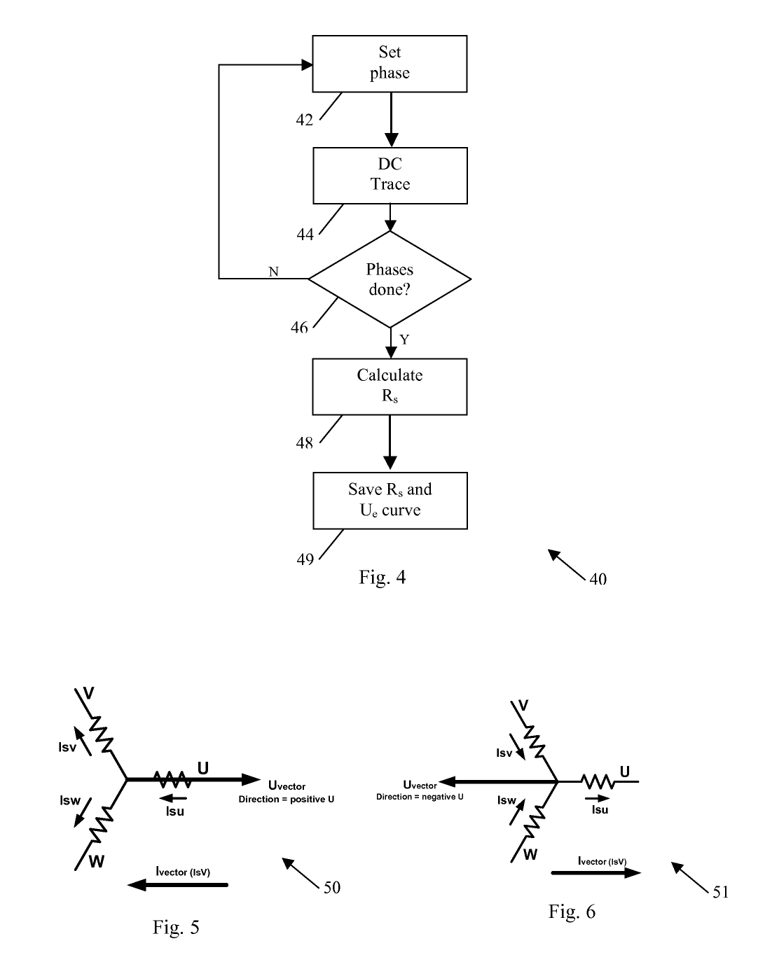

FIG. 4 is a flow chart, indicated generally by the reference numeral 40, of a DC sequence in accordance with an aspect of the present invention. The algorithm 40 starts at step 42 where it is determined which phase of the motor 10 is to be used to inject signals into the motor. The three phases (labeled u, v and w) of an exemplary motor are shown in FIGS. 5 and 6. (Note that although three-phase motors are described, the method is not limited to three phase machines, but can be applied to machines with more or fewer phases.)

As indicated above, it is desirable to keep the motor 10 at standstill. In order to do so, no net torque must be produced at the motor. This is achieved by keeping a voltage vector angle applied to the motor in one direction since a torque is generated when the voltage vector angle rotates.

As described in detail below, the voltage vector direction is changed during the measurement process but this is only done when the voltage vector magnitude is zero and after the motor has been demagnetised. (It may, for example, be assumed that the motor is sufficiently demagnetised after a zero voltage vector has been applied for a given time. The motor current may also be regulated to a zero command, in which case the voltage vector will adjust to drive the stator current to zero.)

FIG. 5 is a vector diagram of the three-phase asynchronous motor 10 with a positive U voltage vector applied. To apply a positive u-phase current vector (Iₛᵤ), a positive U voltage vector is applied (indicating that a current flows into the motor through the u-phase connection). As shown in FIG. 5, if a current flows into the motor through the u-phase connection, then currents must flow out of the motor through the v- and w-phases of the motor (such that negative current vectors Iₛᵥ and I_{sw} are provided).

The phase setting step 42 of algorithm 40 can select one of six vector directions to be applied to the motor 10. The positive U vector shown in FIG. 5 is one option. A second option is a negative U vector as shown in FIG. 6. As shown in FIG. 6, a negative U vector causes current to flow into the motor 10 through the v- and w-phase connections (positive Iₛᵥ and I_{sw}) and causes a current to flow out of the u-phase connection (negative Iₛᵤ).

In addition to positive and negative U vectors, the step 42 can select a positive V vector, a negative V vector, a positive W vector and a negative W vector. The currents that flow in the motor 10 during the testing phase can be very large. In each test, all of the current flows through one of the phase connections of the motor and half of the current flows through each of the other two phase connections (for a three-phase motor). By changing which of the phase connection carries the entire test current, the heat generated in a particular phase of the inverter 8 and the motor 10 can be reduced over the entire sequence. This reduces the likelihood of the inverter 8 and/or the motor 10 being damaged during the test measurements and also reduces the impact of heat on the measurements obtained while allowing multiple measurements to be obtained so that an average estimate can be obtained.

With the phase set at step 42, the algorithm 40 moves to step 44 where a DC trace step is applied. The DC trace step 44 applies a number of differently sized vectors to the motor 10.

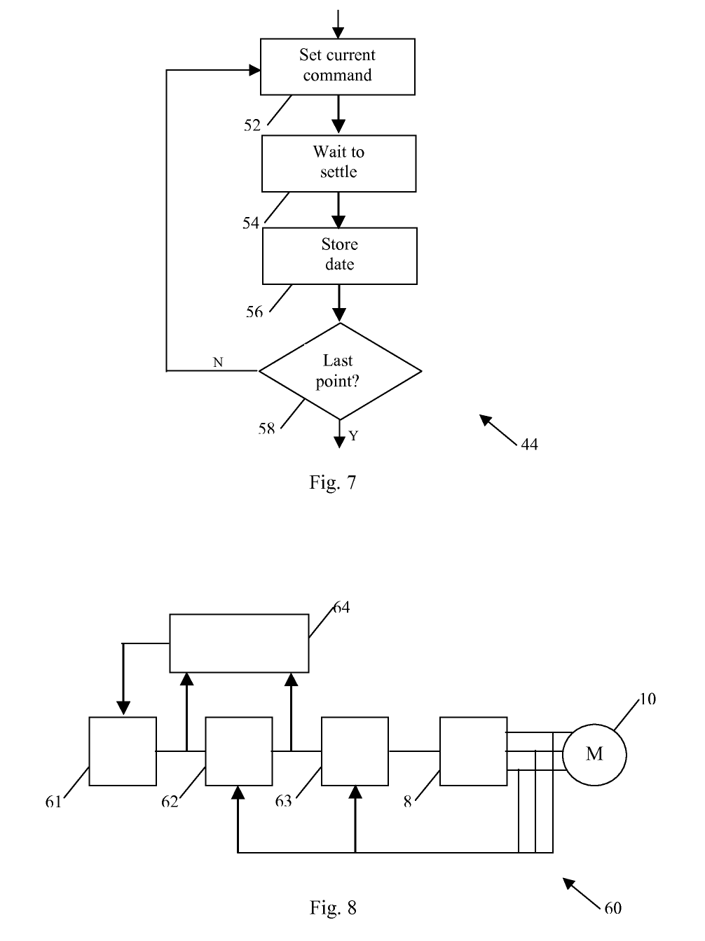

FIG. 7 is a flow chart that shows more detail of the DC trace step 44 of the DC sequence algorithm 40. The DC trace step 44 starts at step 52 where a current command is set. In the event that a positive U vector is being applied (as shown in FIG. 5), the command set step 52 defines the size of the current vector Iₛᵤ being applied.

Next, at step 54, the current vector is given time to settle. The step 54 may be implemented by providing a suitable delay. Alternatively, as described further below, the current vector may be measured so that a decision can be taken regarding when the current vector has settled. Providing a measurement step increases accuracy and potentially increases the speed at which measurements can be taken by avoiding unnecessary delay in waiting for currents to settle when they have, in fact, already settled.

Once the current vector has settled, both the current magnitude and applied voltage measurements are recorded at step 56.

Finally, at step 58, it is determined whether there are any further current levels to be applied for the phase vector concerned. If so, the DC trace step 44 returns to step 52 where a different current vector is applied. If not, the step 44 is complete and the algorithm 40 moves to step 46.

At step 46 of the algorithm 40, it is determined whether any further phases of the motor are to have test vectors applied thereto. If so, the algorithm 40 returns to step 42 where a different phase is selected. The DC trace step 44 is then repeated for that phase and a further set of data is stored (at step 56). If not, the algorithm 40 moves to step 48.

At step 48, the data collected at each instance of the step 56 of the DC trace step 44 is used to determine the stator resistance Rₛ of the motor 10. Finally, at step 49, the Rₛ and Uₑ curves for the motor are stored.

FIG. 8 is a highly schematic block diagram of a motor system, indicated generally by the reference numeral 60, in accordance with an aspect of the present invention. The motor system 60 includes the inverter 8 and the motor 10 of the motor system 1 described above. In addition, the system 60 comprises a DC trace generation module 61, a proportional-integral (PI) controller 62, a pulse width modulation (PWM) module 63 and a DC trace settling detector 64. The modules 61, 62, 63 and 64 form part of the controller 12 of the system 10 described above. An AC power source, rectifier and DC link capacitor (as shown in FIG. 1) would typically be included in the system 60, but these are not shown in FIG. 8.

The DC trace generation module 61 has an output coupled to a first input of the PI controller 62. The PI controller has a second input receiving data concerning current levels in each of the three phase inputs to the motor 10. The PI controller 62 has an output providing a voltage signal to the PWM controller 63. The PI controller 62 sets the voltage so that the current output by the inverter 8 to the motor 10 is as requested by the DC trace generation module 61.

The DC trace settling detector 64 has a first input coupled to the input of the PI controller 62 and a second input coupled to the output of the PI controller.

The DC trace generation module 61 is used to implement step 52 of the DC trace algorithm 44 (i.e. setting the current to be applied to a selected phase of the motor 10). The DC trace settling detector 64 determines when the current command has settled and can therefore be used to implement the step 54 of the DC trace algorithm 44 described above.

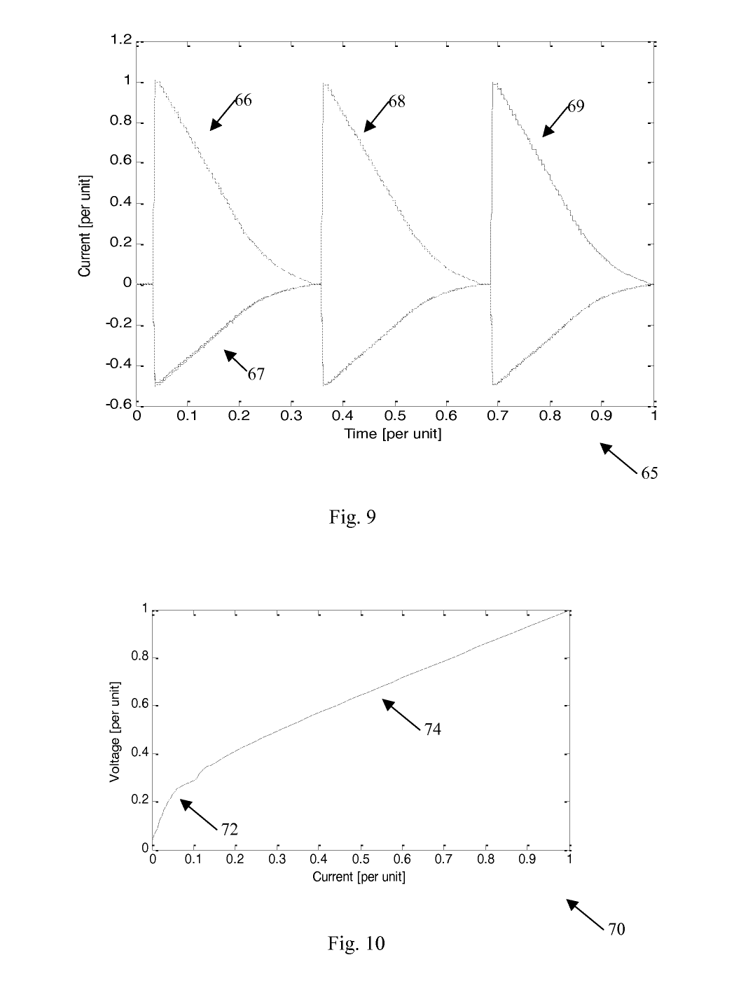

FIG. 9 shows a plot, indicated generally by the reference numeral 65, of applied currents of an exemplary DC sequence. The plot 65 shows the current in each of the three phases of the motor 10. A first pulse 66 is applied to the u-phase of the motor 10. The first pulse 66 is a positive U pulse, and smaller negative V and negative W pulses (indicated generally by the reference numeral 67) occur at the same time (so that the overall current applied to the motor sums to zero). A second pulse 68 is applied to the v-phase of the motor 10 and finally a third pulse 69 is applied to the w-phase of the motor.

Thus, the plot 65 shows an exemplary implementation of the algorithm 40. The algorithm 40 starts at step 42, where a phase of the motor is selected (initially phase u in the plot 65). Next, a DC trace is applied (step 44). The DC trace starts with a high current and the current is progressively reduced until it reaches zero.

As shown in FIG. 9, the pulse 66 comprises a number of steps. Each step of the pulse 66 corresponds to a current set in the current command step 52 of the algorithm 44. As described above with reference to FIG. 8, the current command is set by the DC trace generation module 61 and is allowed to settle (step 54 of the algorithm 44). Once the current has settled, current and voltage outputs of the inverter 8 are measured and stored (step 56 of the algorithm 44) and the current command adjusted.

Once the current is reduced to zero (so that the pulse 66 is complete), the current is kept at zero in all three phases of the motor for a short dwell time before the next pulse is applied. The provision of a dwell time ensures that magnetic flux in the motor reduces to zero before the next pulses are applied. If the dwell time is too short, then rotor flux will remain in the machine and the application of the next pulse would provide a stator flux that will interact with the rotor flux, resulting in torque production in the motor.

With the dwell time complete, the algorithm 40 moves to step 46, where it is determined that further phases need to be tested. The algorithm 40 then returns to step 42 where the v phase is selected. The pulse 68 is applied to the motor 10 in a similar manner to the pulse 66. Once the pulse 68 has been applied, the pulse 69 is applied. Once the pulse 69 is applied, the algorithm 40 moves to steps 48 and 49 where the stator resistance and the Uₑ curve data are determined and stored (as described further below).

In order to protect the drive and motor, the amount of current applied is limited. This can be specified as the lower of the rated drive or motor current, or some factor thereof (e.g. 80% of the rated drive current and 90% of the rated motor current). The resulting voltage required to regulate that current is typically relatively low compared to the rated motor and drive voltages because the machine impedance is low at de excitation (only Rₛ) and there is no back-emf at standstill.

As described above, DC trace data may be collected for all phases of the motor 10 (i.e. positive U, negative U, positive V, negative V, positive W and negative W), However, in some embodiments of the invention, DC trace data is obtained for only a subset of those. For example, only three of the vectors may be used such as the positive U, positive V and positive W directions. Indeed, the exemplary currents shown in FIG. 9 are applied to the positive U, positive V and positive W phases only.

As described above, at step 48, the data collected at each instance of the step 56 of the DC trace step 44 is used to determine the stator resistance Rₛ of the motor 10 and at step 49, the Rₛ and Uₑ curves for the motor 10 are stored.

FIG. 10 shows a plot, indicated generally by the reference numeral 70, of measured currents and voltages as recorded at step 56 of the DC sequence described above. The plot consists of the average of data for 3 traces, one for each phase of the machine in the positive direction. The plot includes a non-linear section (indicated generally by the reference numeral 72) and a linear section (indicated generally by the reference numeral 74). The stator resistance estimate for the motor under test is determined using linear regression of de sequence data at higher current levels (i.e. in the linear region) to determine the slope (resistance). The estimation of the stator resistance can also be performed using non-linear regression analysis of the data. For example, the data could be fit to the non-linear function v_{trace}=v_{drop}(1−e^{-ki}^{_{trace}})+rₛi_{trace} to determine the parameters v_{drop}, k and rₛ.

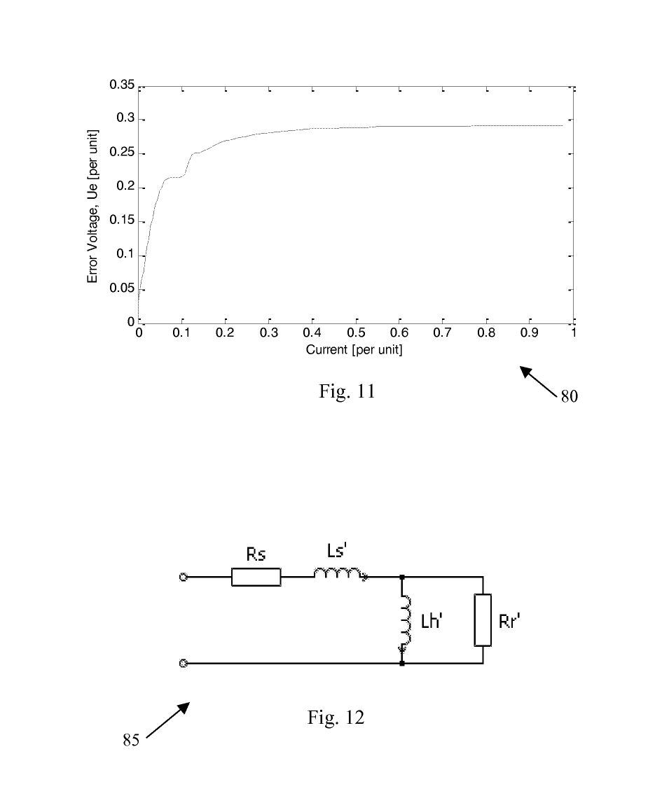

FIG. 11 shows an exemplary Uₑ curve, indicated generally by the reference numeral 80. The Uₑ curve is simply the residual remaining after the resistive voltage drop is subtracted from the trace data.

Ue=V(I)−Rhat*I, where Rhat (R, ̂) is the estimated stator resistance determined via the regression analysis.

As described above, the algorithm 20 includes a DC sequence step 22 and an AC sequence step 24. The DC sequence step 22 has been described above with reference to FIGS. 4 to 11. The AC sequence step 24 is described below.

The AC sequence is used to measure the nominal transient inductance, the magnetizing stator inductance and the rotor resistance. The nominal stator inductance is the sum of the main inductance Lₕ and the stator leakage inductance Lₛₗ as shown in the equivalent circuit 30 described above.

FIG. 12 is a transformed electrical equivalent circuit of a motor at standstill, with the values referred to the stator side that is used in the AC sequence step described below. The equivalent circuit, indicated generally by the reference numeral 85, includes a stator resistance Rₛ, a referred stator inductance Lₛ′, a referred main inductance Lₕ′ and a referred rotor resistance Rᵣ′, wherein:

$${L}_{{s}^{′}} = {L}_{s} - \frac{{L}_{h}^{2}}{{L}_{r}} \approx {L}_{sl} + {L}_{rl}$$

$${L}_{{h}^{′}} = \frac{{L}_{h}^{2}}{{L}_{r}}$$

$${R}_{{r}^{′}} = \frac{{L}_{h}^{2}}{{L}_{r}^{2}} {R}_{r}$$

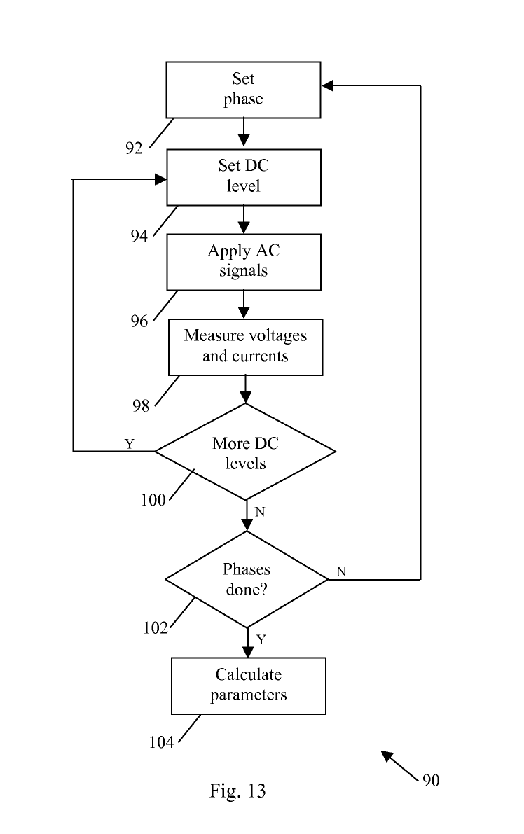

FIG. 13 is a flow chart, indicated generally by the reference numeral 90, of an AC sequence in accordance with an aspect of the present invention.

The algorithm 90 starts at step at step 92 where it is determined which phase of the motor 10 is to be used to inject signals into the motor (e.g. the phases u, v and w as described above). In a similar manner to the DC sequence algorithm 40, the AC sequence is applied to different phases of the motor in order to spread heat around the inverter 8 and the motor 10 over the entire AC sequence.

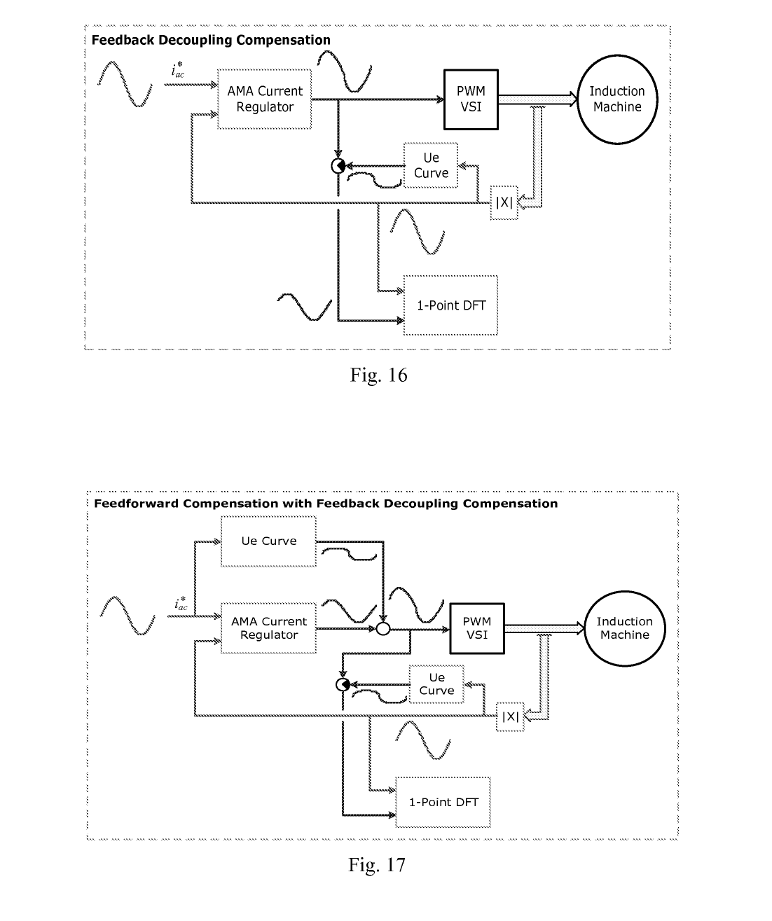

With the phase set at step 92, the algorithm 90 moves to step 94 where a DC level is set. Next, at step 96, an AC signal, having the DC offset set in step 94 is applied to the motor phase selected at step 92. Three basic AC signals are used. First, a high frequency signal is injected for estimating the transient machine inductance. Second, a low frequency injection is used to estimate the mutual (magnetizing) inductance. Finally, the slip frequency is injected to estimate the rotor resistance. The Uₑ curve determined in the de sequence can be used to compensate for the inverter nonlinearity in either the command voltage (feedforward compensation—for example as shown in FIG. 15), the feedback voltage used for processing (feedback decoupling compensation—for example as shown in FIG. 16) or a combination thereof (for example as shown in FIG. 17). Of course, many other regulation arrangements other than those shown in FIGS. 15 to 17 could be used.

The current regulator has the characteristic of being able to regulate both de and an ac waveform. For low injection frequencies, the PI regulator 62 used in the de sequence is adequate. However, for the high frequency injection, a resonant current regulator could be employed to increase the magnitude of the ac quantity.

A number of current and/or voltage measurements are taken at step 98 and stored for making calculations later. The applied or measured voltages and measured currents are processed using a single frequency discrete Fourier Transform (DFT) to determine the magnitude and phase of the voltage and current at the injection frequency. The magnitude of the voltage, the magnitude of the current and phase of current relative to the voltage are stored for calculation.

The algorithm moves to step 100, where it is determined whether AC signals with different DC offsets are to be applied to the motor phase selected at step 92. If more DC steps are to be applied, the algorithm 90 returns to step 94 where another DC level is selected. If not, the algorithm 90 moves to step 102.

At step 102, it is determined whether or not AC signals are to be applied to any other phases of the motor. If so, the algorithm 90 returns to step 92 where a further phase is selected. If not, the algorithm 90 moves to step 104.

At step 104, the currents and voltages stored in each instance of step 98 of the algorithm 90 are used to calculate the transient inductance, mutual inductance and rotor resistance of the motor 10.

The transient inductance can be determined from the ratio of the applied voltage magnitude over the current times frequency that is 90 degrees lagging the applied voltage. Once the transient inductance is determined, the dynamic mutual inductance can be determined. The dynamic mutual inductance is the ratio of the magnetizing voltage magnitude (applied voltage minus IR drop and transient impedance drop) over the current times frequency that is 90 degrees lagging the magnetizing voltage.

$${DL}_{h}^{′} = \frac{{AbsUh}^{′}}{{ω}_{A C} \cdot \vert \overline{{i}_{h}^{′}} \vert}$$

To determine the stator inductance, the dynamic mutual inductance is integrated over the current to arrive at the magnetizing flux.

ψₕ′=∫DLₕ′dIsV_{A0}

The mutual inductance is then calculated from the magnetizing flux:

$${L}_{h}^{′} = \frac{{ψ}_{h}^{′}}{{IsV}_{A 0}}$$

Then the stator inductance is determined by adding the transient inductance to the mutual inductance:

Lₛ=Lₕ′+Lₛ′

The rated stator inductance is determined by determining the current required to reach the nominal stator flux (determined from nameplate data), and identifying the corresponding stator inductance at that current level.

ψₛ=Lₛ·IsV_{A0}

The rotor resistance is the complimentary calculation to the dynamic mutual inductance calculation. It is the ratio of the magnetizing voltage magnitude (applied voltage minus IR drop and transient impedance drop) to the over the current that is in phase with the magnetizing voltage.

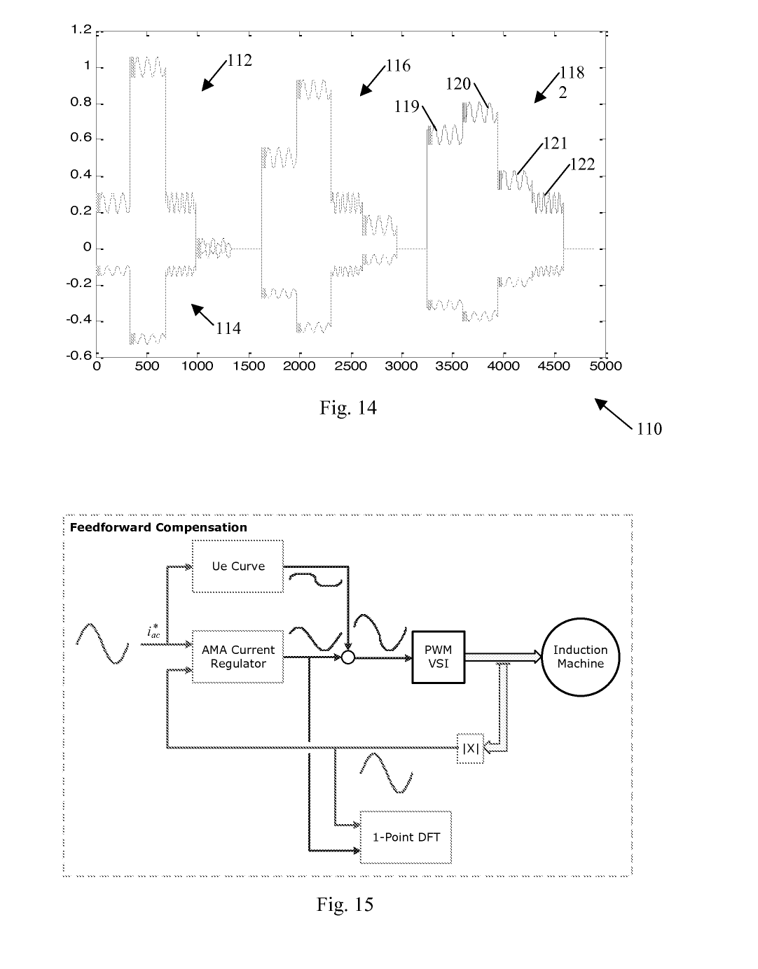

FIG. 14 shows a plot of current versus time, indicated generally by the reference numeral 110, of applied currents of an exemplary AC sequence. The plot 110 shows the current in each of the three phases of the motor 10. A first AC sequence 112 is applied to the u-phase of the motor 10. The first pulse 112 is a positive U pulse, and smaller negative V and negative W sequences (indicated generally by the reference numeral 114) occur at the same time (so that the overall current applied to the motor sums to zero). A second AC sequence 116 is applied to the v-phase of the motor 10 and finally a third AC sequence 118 is applied to the w-phase of the motor.

The plot 110 shows an exemplary implementation of the algorithm 90. The algorithm 90 starts at step 92, where a phase of the motor is selected (initially phase u in the plot 110). Next, a number of different DC offset levels are selected in turn (implementing steps 94 to 100 of the algorithm 90). With the AC sequence complete for the positive U phase, AC sequences are then applied to the positive V phase and the positive W phase in turn. AC sequences could also be applied to one or more of the negative U, V and W phases in some implementations of the invention.

Note that, in common with the DC sequence algorithm described above, once the current is reduced to zero after an AC sequence is completed, the current is kept at zero in all three phases of the motor for a short dwell time before a pulse of a different phase of the motor is applied. As described above, the provision of a dwell time ensures that magnetic fluxes in the motor reduce to zero before the next pulses if applied. If the dwell time is too short, then rotor flux will remain in the machine and the application of the next pulse would provide a stator flux that would interact with the rotor flux, resulting in torque production in the motor.

The third AC sequence 118 of the plot 110 includes a first part 119 having a DC offset of about 63% of the allowable de current, a second part 120 having a DC offset of about 75%, a third part 121 having a DC offset of about 38% and a fourth part having a DC offset of about 25%. In total, the current levels are chosen so that the resistive power loss (I²R) in each phase is balanced over the entire sequence.

As shown in FIG. 14, the first part 119 starts with a high frequency portion providing a high frequency injection at the designated DC offset. This is followed by a low frequency injection. The second part 120 and the third part 121 are similarly structured, with an initial high frequency portion and a following low frequency portion. The fourth part 122 is at the rated slip frequency for the machine.

As described above, the AC sequence is used to estimate the transient inductance, mutual inductance and rotor resistance and consists of three portions, which could be conducted in any order and may be combined. The tests are conducted at various DC levels so that the saturation of the mutual inductance can be characterized. The first portion consists of high frequency injection that might typically be of the order of four to six times the rated machine frequency and is used to estimate the transient inductance. The second portion consists of a low frequency portion used to measure the dynamic mutual inductance. This is then integrated and the transient inductance is included in order to arrive at the stator inductance. The third portion is a mid-frequency injection at the rated slip frequency and is used to estimate the rotor resistance. The third portion is conducted at a current of the order of 25% of the rated machine current.

As shown in FIG. 14, the AC sequences 112, 116 and 118 each have three sequences at different DC levels that comprise a high frequency portion and a low frequency portion as well as a fourth sequence having a mid-frequency signal. The nine de levels of the first and second portions shown in FIG. 14 are spread out amongst the three machine phases in such a way that the total power losses are approximately equivalent for each phase. The levels are sequenced in each phase such that the second level is highest and the third level is lowest, thereby minimizing the dwell time and transition between the phases. The third portion is inserted so that either the last or next to last level for each phase, depending on the de levels. Of course, although nine de levels spread across three phases of the motor system are chosen in the exemplary embodiment described herein, the present invention could be implemented with any number of de levels, including non-powers of three (such as eight or ten de levels). The goal is to balance the losses and still obtain high quality measurements.

The embodiments of the invention described above are provided by way of example only. The skilled person will be aware of many modifications, changes and substitutions that could be made without departing from the scope of the present invention. The claims of the present invention are intended to cover all such modifications, changes and substitutions as fall within the spirit and scope of the invention.

What is claimed is:

1. A method of determining electromagnetic characteristics of an asynchronous motor system, the method comprising applying a DC sequence to the motor system and applying an AC sequence to the motor system, wherein the DC sequence includes applying a first DC sequence to a first phase of the motor system and applying a second DC sequence to a second phase of the motor system an d the AC sequence includes
applying an AC sequence to a third and/or a fourth phase of the motor system, the first and second DC sequences each comprising:
setting a first DC current level for application to the motor system and measuring the current(s) and/or the voltage(s) applied to the motor system in response to the setting of the first DC current level;
adjusting the applied DC current level and measuring the current(s) and/or voltage(s) applied to the motor in response to the adjusted DC current level; and
repeating the adjusting and measuring step until the respective DC sequence is complete.

2. The method as claimed in claim 1, wherein for each DC current level applied during one of the DC sequences, the motor is given time to settle before the voltage and/or current measurements are taken.

3. The method as claimed in claim 2, further comprising monitoring currents applied to the motor to determine when the applied DC current level has settled.

4. The method as claimed in claim 1, wherein the AC sequence includes applying a first AC sequence to the third phase of the motor system and applying a second AC sequence to the fourth phase of the motor system, the first and second AC sequences each comprising:
setting a first DC offset level;
applying one or more AC signals to the respective phase of the motor system, the AC signals including the set DC offset level and measuring the current(s) and/or the voltage(s) applied to the motor system in response to the applied AC signals;
adjusting the DC offset level, applying one or more AC signals to the respective phase of the motor system including the adjusted DC offset level and measuring the current(s) and/or voltage(s) applied to the motor in response to the applied signal; and
repeating the adjusting and measuring step until the respective AC sequence is complete.

5. A method of determining electromagnetic characteristics of an asynchronous motor system, the method comprising applying a DC sequence to the motor system and applying an AC sequence to the motor system, wherein the DC sequence includes applying a DC sequence to a first and/or a second phase of the motor system and the AC sequence includes applying a first AC sequence to a third phase of the motor system and applying a second AC sequence to a fourth phase of the motor system, the first and second AC sequences each comprising:
setting a first DC offset level;
applying one or more AC signals to the respective phase of the motor system, the AC signals including the set DC offset level and measuring the current(s) and/or the voltage(s) applied to the motor system in response to the applied AC signals;
adjusting the DC offset level, applying one or more AC signals to the respective phase of the motor system including the adjusted DC offset level and measuring the current(s) and/or voltage(s) applied to the motor in response to the applied signal; and
repeating the adjusting and measuring step until the respective AC sequence is complete.

6. The method as claimed in claim 4, wherein applying one or more AC signals to the respective phase of the motor system comprises applying one or more of a high frequency signal, a low frequency signal and a slip frequency.

7. The method as claimed in claim 4, wherein the DC offset levels of the AC sequences are spread out amongst the phases of the motor system in such a way that the total power losses are approximately equivalent for each phase.

8. The method as claimed in claim 1, wherein the DC and AC sequences are applied such that any torque created within the motor system is minimized.

9. The method as claimed in claim 1, wherein the DC sequence further comprises applying a third DC sequence to a fifth phase of the motor system.

10. The method as claimed in claim 1, wherein the AC sequence further comprises applying third AC sequence to a sixth phase of the motor system.

11. The method as claimed in claim 1, further comprising using data obtained from the application of the DC sequence to determine stator resistance of the motor and/or non-linearity of an inverter used to drive the motor.

12. The method as claimed in claim 1, further comprising using data obtained from the application of the AC sequence to determine nominal stator transient inductance, magnetizing inductance and/or rotor resistance of the motor.

13. The method as claimed in claim 1, wherein the first and second phases of the motor system are selected from: a positive U vector, a negative U vector, a positive V vector, a negative V vector, a positive W vector and a negative W vector.

14. The method as claimed in claim 1, wherein the third and fourth phases of the motor system are selected from: a positive U vector, a negative U vector, a positive V vector, a negative V vector, a positive W vector and a negative W vector.

15. The method as claimed in claim 2, wherein the AC sequence includes applying a first AC sequence to the third phase of the motor system and applying a second AC sequence to the fourth phase of the motor system, the first and second AC sequences each comprising:
setting a first DC offset level;
applying one or more AC signals to the respective phase of the motor system, the AC signals including the set DC offset level and measuring the current(s) and/or the voltage(s) applied to the motor system in response to the applied AC signals;
adjusting the DC offset level, applying one or more AC signals to the respective phase of the motor system including the adjusted DC offset level and measuring the current(s) and/or voltage(s) applied to the motor in response to the applied signal; and
repeating the adjusting and measuring step until the respective AC sequence is complete.

16. The method as claimed in claim 3, wherein the AC sequence includes applying a first AC sequence to the third phase of the motor system and applying a second AC sequence to the fourth phase of the motor system, the first and second AC sequences each comprising:
setting a first DC offset level;
applying one or more AC signals to the respective phase of the motor system, the AC signals including the set DC offset level and measuring the current(s) and/or the voltage(s) applied to the motor system in response to the applied AC signals;
adjusting the DC offset level, applying one or more AC signals to the respective phase of the motor system including the adjusted DC offset level and measuring the current(s) and/or voltage(s) applied to the motor in response to the applied signal; and
repeating the adjusting and measuring step until the respective AC sequence is complete.

17. The method as claimed in claim 5, wherein applying one or more AC signals to the respective phase of the motor system comprises applying one or more of a high frequency signal, a low frequency signal and a slip frequency.

18. The method as claimed in claim 5, wherein the DC offset levels of the AC sequences are spread out amongst the phases of the motor system in such a way that the total power losses are approximately equivalent for each phase.

19. The method as claimed in claim 6, wherein the DC offset levels of the AC sequences are spread out amongst the phases of the motor system in such a way that the total power losses are approximately equivalent for each phase.
